(19) United States
(12) Patent Application Publication
(10) Pub. No.: US 2008/0155363 A1
(43) Pub. Date: Jun. 26, 2008

(54) BIST CIRCUIT DEVICE AND SELF TEST METHOD THEREOF

(75) Inventor: Koji Kohara, Yokohama-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/958,737

(22) Filed: Dec. 18, 2007

(30) Foreign Application Priority Data
Dec. 20, 2006 (JP) 2006-343167

(51) Int. Cl. G11C 29/00; G06F 11/27

(52) U.S. Cl. 714/719; 714/733; 714/E11.169

(57) ABSTRACT

A BIST circuit device includes a test memory, a test result storage memory having the capacity equal to or larger than the capacity of the test memory, and a control circuit which performs a test for the test memory at an actual application frequency and stores the test result into the test result storage memory.

### CROSS-REFERENCE TO RELATED APPLICATIONS

This application is based upon and claims the benefit of priority from prior Japanese Patent Application No. 2006-343167, filed Dec. 20, 2006, the entire contents of which are incorporated herein by reference.

### BACKGROUND OF THE INVENTION

1. Field of the Invention

This invention relates to a BIST circuit device (BIST: Built-In Self Test) and a self test method thereof and is applied to, for example, a BIST circuit device having a plurality of memory cells mounted on a chip and a test method thereof.

2. Description of the Related Art

Conventionally, in the self test method for the BIST circuit device, for example, a PLL circuit (Phase Locked Loop circuit: a circuit which outputs a signal at a frequency equal to an integral multiple of the frequency of an input signal and is used when a high-frequency clock is generated in the chip) is used in some cases. For example, in Jpn. Pat. Appln. KOKAI Publication No. 2001-14890, a semiconductor device in which some of the memories are used as relief analysis memories is described. However, in this case, a memory to be tested is subjected to a fault test at a product actual application frequency (at-speed), but it is difficult to specify a faulty portion. Therefore, it is difficult to find out the cause of the fault at the product application frequency and make improvements by a process or the like.

Further, a method for specifying a faulty portion of the memory is provided by use of a method for serially outputting read results of the memory for each word line used to specify the faulty portion. However, if the PLL circuit is used, it is difficult to control the shift-out timing from the exterior. Since the memory repeatedly performs the immediately preceding operation while the shift-out process is being performed, the faulty portion will not reappear depending on the operation sequence. Further, as a different method, it is considered to hold one address or a plurality of addresses at the starting time of appearance of the fault, but the number of addresses of the faulty portions which can be held is limited and it is inconvenient to analyze the cause of the fault.

As described above, in the conventional BIST circuit device and the self test method thereof, it tends to become difficult to specify a faulty portion at the product actual application frequency. Particularly, the tendency to make it difficult to specify the faulty portion becomes significant when the product application frequency becomes high.

### BRIEF SUMMARY OF THE INVENTION

According to one aspect of the present invention, there is provided a BIST circuit device including a test memory, a test result storage memory having capacity not smaller than capacity of the test memory, and a control circuit which performs a test for the test memory at an actual application frequency and stores the test result into the test result storage memory.

According to another aspect of the present invention, there is provided a BIST circuit device including a plurality of test memories, a test result storage memory having capacity not smaller than capacity of the test memories, and a control circuit which performs tests for the test memories at an actual application frequency and stores the test results into the test result storage memory.

According to still another aspect of the present invention, there is provided a self test method for a BIST circuit device which includes a test memory, a test result storage memory having capacity not smaller than capacity of the test memory and a control circuit including causing the control circuit to perform a test for the test memory at an actual application frequency and causing the test result to be stored into the test result storage memory.

### BRIEF DESCRIPTION OF THE SEVERAL VIEWS OF THE DRAWING

FIG. 1 is a block diagram showing a BIST circuit device according to a first embodiment of this invention;

FIG. 2 is a block diagram for illustrating a test memory shown in FIG. 1;

FIG. 3 is a circuit diagram showing one example of the configuration of a memory cell (SRAM cell) in FIG. 1;

FIG. 4 is a circuit diagram showing one example of the configuration of an input circuit in FIG. 1;

FIG. 5 is a flow diagram for illustrating the self test method of the BIST circuit device according to the first embodiment;

FIG. 6 is a block diagram for illustrating one step (step ST1) in FIG. 5;

FIG. 7 is a block diagram for illustrating one step (step ST2) in FIG. 5;

FIG. 8 is a block diagram for illustrating one step (step ST3) in FIG. 5;

FIG. 9 is a timing chart showing the test sequence of the steps ST1 to ST3 in FIG. 5;

FIG. 10 is a block diagram for illustrating one step (step ST4) in FIG. 5;

FIG. 11 is a block diagram showing a BIST circuit device according to a second embodiment of this invention;

FIG. 12 is a block diagram showing a BIST circuit device according to a third embodiment of this invention;

FIG. 13 is a block diagram for illustrating a concept of a BIST circuit device according to the third embodiment;

FIG. 14 is a block diagram showing a BIST circuit device according to a fourth embodiment of this invention;

FIG. 15 is a block diagram for illustrating a concept of a BIST circuit device according to the fourth embodiment; and

FIG. 16 is a block diagram showing a BIST circuit device as a comparison example.

### DETAILED DESCRIPTION OF THE INVENTION

There will now be described embodiments of the present invention with reference to the accompanying drawings. In the above explanation, common portions throughout the drawings are denoted by the common reference symbols.

### First Embodiment

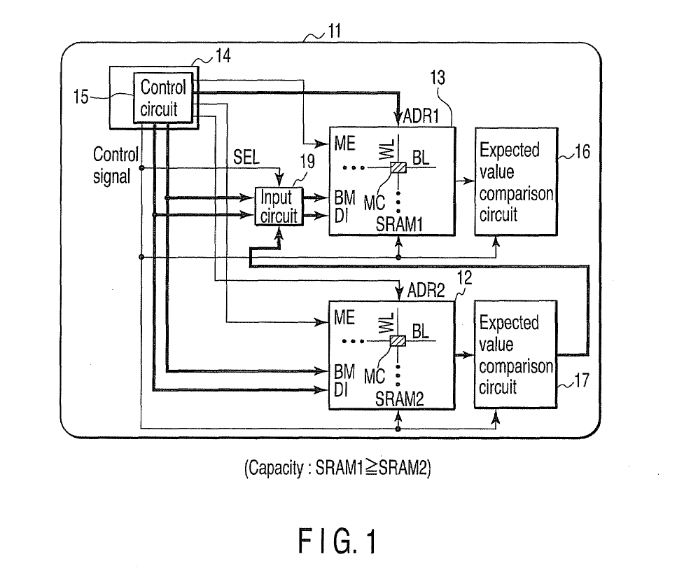

First, one example of the configuration of a BIST circuit device according to a first embodiment of this invention is explained with reference to FIGS. 1 to 5. FIG. 1 is a block diagram showing the BIST circuit device according to the first embodiment.

<1-1. Configuration Example of BIST Circuit Device>

As shown in the drawings, a BIST circuit device 11 according to the present embodiment includes a test memory 12, a test result storage memory 13, a BIST circuit 14 having a control circuit 15, expected value comparison circuits 16, 17 and an input circuit 19.

The test memory (SRAM 2) 12 is a memory to be tested in the self test operation as will be explained later. In the case of this example, the test memory 12 is an SRAM (Static Random Access Memory). The test memory 12 has a plurality of memory cells MC arranged in intersecting positions between word lines WL (read/write control lines) and bit lines BL (/BL) in a matrix form. As will be described later, the memory cells MC of a number corresponding to the I/O width are simultaneously accessed by use of a word address.

Further, the test memory 12 has a function of rewriting only a specified bit (bit masked write).

The test result storage memory (SRAM1) 13 is a memory to store the test result of the test memory 12 in the self test operation as will be explained later. A normal test can be made for the SRAM 1 as well as the SRAM 2 and tests can be equally made for both of the memories in the normal mode. In the case of this example, the test result storage memory 13 is an SRAM like the test memory 12. The test result storage memory 13 has a plurality of memory cells MC arranged in intersecting positions between word lines WL (read/write control lines) and bit lines BL (/BL) in a matrix form. Like the above case, the memory cells MC of a number corresponding to the I/O width are simultaneously accessed by use of a word address.

In the case of this example, the capacity of the test result storage memory 13 is set equal to or larger than the capacity of the test memory 12 (Capacity: SRAM1≧SRAM2). That is, the number of words and the number of I/Os of the test result storage memory (SRAM1) 13 are respectively set equal to or larger than those of the test memory (SRAM2) 12.

The control circuit 15 in the BIST circuit 14 is operated by using an actual application frequency (at-speed) generated by an external PLL circuit (Phase Locked Loop circuit: a circuit which outputs a signal at a frequency equal to an integral multiple of the frequency of an input signal and is used when a high-frequency clock is generated in the chip) or the like as a clock. Then, the function test for the test memory 12 is made at the actual application frequency (at-speed) and the test result is stored into the test result storage memory 13. The specific details will be described later, but the control circuit 15 performs a function test to determine whether the memory cell MC in the test memory 12 is correctly operated at the actual application frequency or not.

The expected value comparison circuit 17 is configured to compare the test result of the test memory 12 with an expected value and output the comparison result to the input circuit 19.

The expected value comparison circuit 16 is configured to have a function of comparing data read out from the test result storage memory 13 with an expected value and outputting the comparison result and a function of reading out the contents of the memory at low speed. In addition, the expected value comparison circuit 16 can perform the normal test.

The input circuit 19 is configured to select a signal such as a data signal DI or the like according to a control signal SEL input from the control circuit 15 and output the thus selected signal to the test result storage memory 13.

<1-2. Example of Memory Configuration>

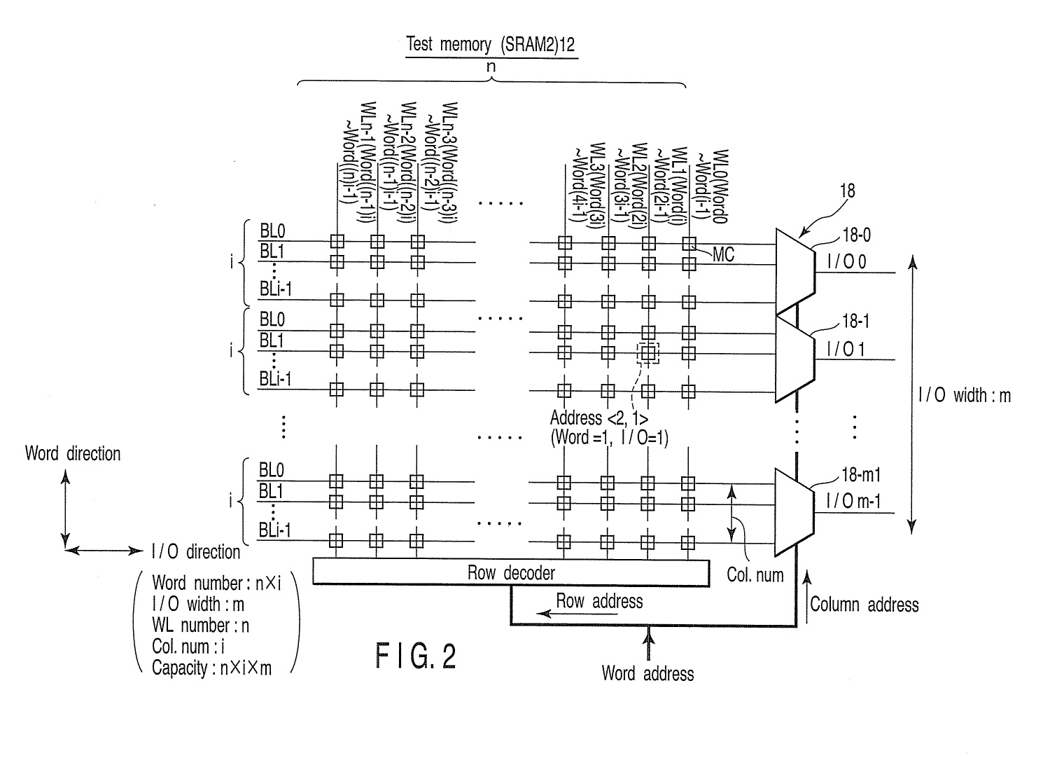

Next, examples of the configurations of the test memory (SRAM2) 12 and test result storage memory (SRAM1) 13 are explained with reference FIG. 2. In this explanation, a case wherein the test memory (SRAM2) 12 is taken as an example is explained.

As shown in FIG. 2, the test memory (SRAM2) 12 has a memory cell array, row decoder and column selection circuit 18.

In the memory cell array, memory cells (SRAM cells) MC are arranged in intersecting positions between word lines WL0 to WLn-1 and bit lines BL0 to BLi-1 in a matrix form.

As shown in FIG. 2, in the case of this example, they are defined as follows. That is, the I/O width is m (I/O width: m), the number of word lines WL (WL number) is n (WL number: n) and the number of bit lines (col. number) for one I/O width is i (col. number: i). Further, the number of memory cells MC (Word number) for one I/O width is n×i (Word number: n×i) and the capacity is the product of the word number and the I/O width (capacity: Word number×I/O width=n×i×m).

Therefore, the word lines WL0 to WLn-1 are used as one unit to access a plurality of words. For example, the word line WL0 is provided as one unit to access a plurality of words Word0 to Word(i-1).

The bit lines BL0 to BLi-1 are selected as one unit by the column selection circuit 18 and connected to I/O lines. For example, the bit lines BL0 to BLi-1 are selected as one unit as I/O1 by a column selection circuit 18-1. For example, the bit lines BL0 to BLi-1 are provided by using approximately 16 bit lines as one unit.

The memory cells MC are accessed for each common word line WL with the plurality of Words used as one unit and for each I/O width with a plurality of bit lines BL selected by the column selection circuit 18 used as one unit.

Then, the memory cell MC to be accessed is determined by a word address and I/O address. For example, a memory cell MC<2,1> accessed by a word address 1 (Word=1) and I/O address 1 (I/O=1) is set to a memory cell provided in a position indicated by the broken lines in FIG. 2.

The row decoder is configured to select preset word lines WL0 to WLn-1 according to an input row address (Row Address).

The column selection circuit 18 is configured to select preset bit lines BL0 to BLi-1 according to an input column address (col. Address) and output data items to I/O0 to I/Om-1 as read data items. The read data items output to I/O0 to I/Om-1 are amplified and sensed by a sense amplifier S/A (not shown).

<1-3. Configuration Example of Memory Cell (SRAM Cell) MC>

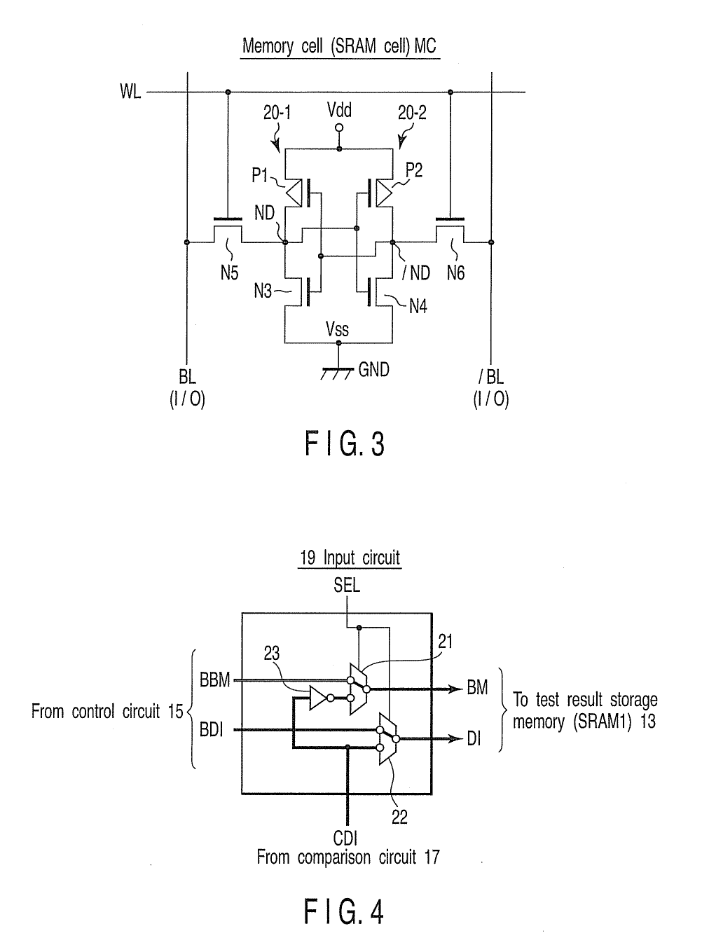

Next, the memory cells (SRAM cells) MC provided in the test memory 12 and test result storage memory 13 are explained with reference to FIG. 3. In this example, a case wherein the memory cell MC in the test memory 12 is taken as an example is explained.

As shown in FIG. 3, the memory cell MC is arranged in an intersecting position between a word line WL (read/write control line) and bit lines BL, /BL. As described above, the contents of the memory cells MC of a number corresponding to the number of I/Os are accessed by each word (Word) address. In the case of this example, the memory cell MC is configured by transfer transistors (Transfer Tr) N5, N6 and inverter circuits 20-1, 20-2 connected in a flip-flop form to store data.

One end of the current path of the transfer transistor N5 is connected to the bit line BL, the other end thereof is connected to a node ND of the inverter circuit 20-1 and the gate of the transistor is connected to the word line WL. Further, one end of the current path of the transfer transistor N6 is connected to the bit line /BL, the other end thereof is connected to a node /ND of the inverter circuit 20-2 and the gate of the transistor is connected to the word line WL.

The inverter circuit 20-1 includes a load transistor (Load Tr or pull-up Tr) P1 and driver transistor (Driver Tr or pull-down Tr) N3. One end (Vss) of the current path of the driver transistor N3 is connected to a ground node GND, the other end thereof is connected at the node ND to one end of the current path of the load transistor P1 and the gate of the transistor is connected to the gate of the load transistor P1 and the node /ND of the inverter circuit 20-2. The other end of the current path of the load transistor P1 is connected to an internal power source Vdd.

The inverter circuit 20-2 includes a load transistor P2 and driver transistor N4. One end (Vss) of the current path of the driver transistor N4 is connected to the ground node GND, the other end thereof is connected at the node /ND to one end of the current path of the load transistor P2 and the gate of the transistor is connected to the gate of the load transistor P2 and the node ND of the inverter circuit 20-1. The other end of the current path of the load transistor P2 is connected to the internal power source Vdd.

Since the memory cell MC provided in the test result storage memory 13 has the same configuration as that described above, the detail explanation thereof is omitted.

<1-4. Configuration Example of Input Circuit>

Next, one example of the configuration of the input circuit 19 in the present embodiment is explained with reference to FIG. 4. As shown in FIG. 4, the input circuit 19 of this example includes selectors 21, 22 and an inverter 23.

The selector 21 is configured to select one of a bit mask test signal BBM input from the control circuit 15 at the normal test time and a logical NOT signal of an expected value comparison result CDI input from the expected value comparison circuit 17 according to a control signal SEL and output the thus selected signal as a bit mask signal BM to the test result storage memory 13.

The selector 22 is configured to select one of a normal test input signal BDI input from the control circuit 15 and an expected value comparison result CDI input from the expected value comparison circuit 17 according to a control signal SEL and output the thus selected signal as a data signal DI to the test result storage memory 13.

The inverter 23 is configured to invert the expected value comparison result CDI input from the expected value comparison circuit 17 and output the thus inverted signal to the selector 21.

<2-1. Self Test Operation>

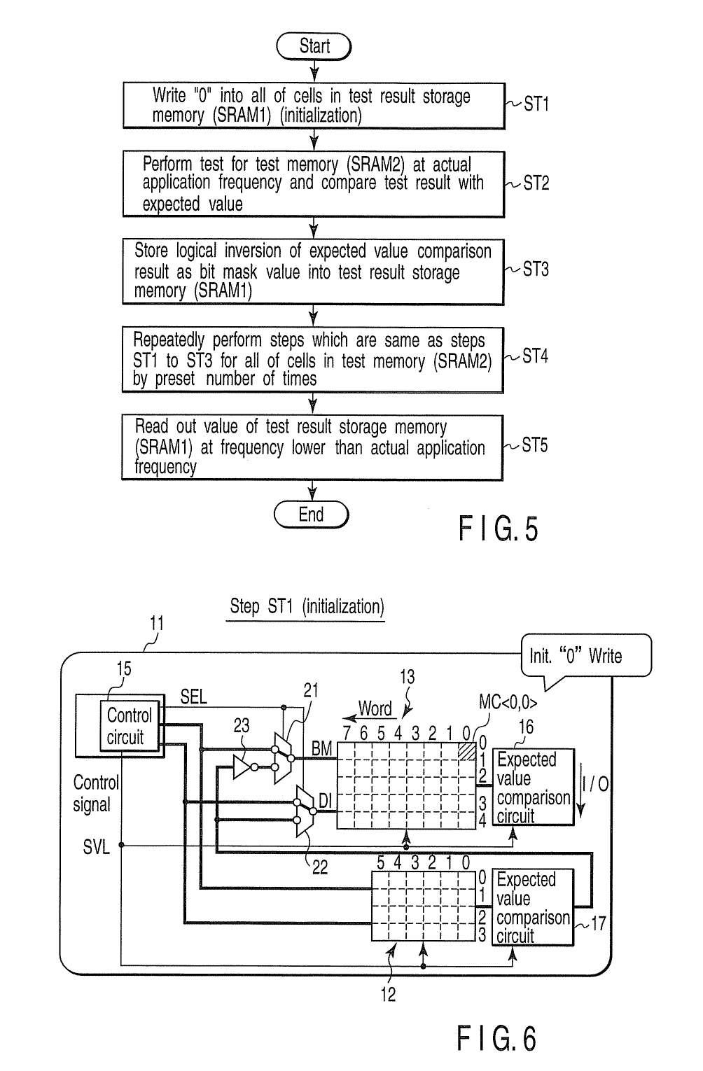

Next, the self test operation of the BIST circuit device according to the present embodiment is explained with reference to FIG. 5 to 10. The explanation is made below based on the flowchart of FIG. 5.

(Step ST0 (Initial State: BIST Test))

First, the memories 12 and 13 are simultaneously tested (BIST test) by use of a tester connected to the BIST circuit device 11 from the exterior before and after the self test operation is performed (initial state) (not shown).

At this time, a test signal from the control circuit 15 is simultaneously input to the memories 12 and 13 via the input circuit 19.

(Step ST1 (Initialization))

Then, as shown in FIG. 6, the control circuit 15 writes “0” data into all of the memory cells MC in the test result storage memory (SRAM1) 13 (initialization).

Therefore, for example, “0” data is written into the memory cell MC<0,0> (Word=0, I/O=0) in the test result storage memory (SRAM1) 13.

(Step ST2 (Test by use of Actual Application Frequency (at-Speed))

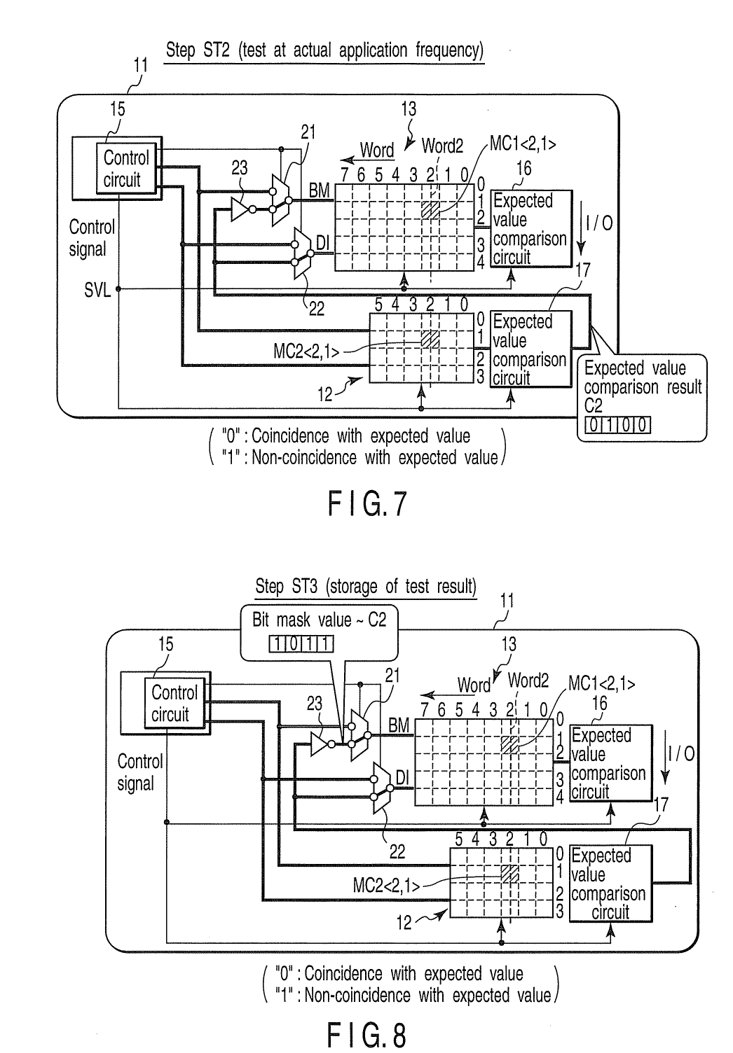

After this, as shown in FIG. 7, the control circuit 15 outputs a control signal SEL to the control terminals of the selectors 21, 22 and switches the input of the input circuit 19 to output signals C0 to CN (N: 1, 2, 3, . . . ) of the expected value comparison circuit 17.

Next, the control circuit 15 is operated by using the actual application frequency (at-speed) generated from an external PLL circuit or the like as a clock, transmits a test signal to the test memory 12 and reads out data from the memory cells MC of a number corresponding to the I/O width for each Word in the test memory 12.

For example, the actual application frequency (at-speed) is a frequency higher than approximately two to fifty times the frequency used at the read time (step ST5) which will be described later and is set to approximately 100 MHz to 500 MHz.

Then, data read out from the test memory 12 is compared with the expected value by the expected value comparison circuit 17 and an expected value comparison result is output.

After this, the expected value comparison circuit 17 outputs the above test results C0 to CN to the input circuit 19.

For example, a case wherein the memory cell MC<2,1> (Word=2, I/O=1) at the address (Word=2, I/O=1) among the memory cells MC subjected to the read operation for Word2 (word number 2) in the test memory 12 is detected to be a faulty cell as the expected value comparison result is explained as an example.

In this case, the expected value comparison circuit 17 outputs the expected value comparison result C2 “0100” (Word=2, I/O=0, 1, 2, 3) in Word2 to the input circuit 19. In this example, “0” in the expected value comparison result indicates coincidence with the expected value and “1” indicates non-coincidence with the expected value.

(Step ST3 (Test Result Storage))

Next, as shown in FIG. 8, the input circuit 19 outputs bit mask values BM (logical inversion) obtained by inverting the input expected value comparison results C0 to CN by use of the inverter 23 and supplying the inverted signals via the selector 21 and data DI supplied via the selector 22 to the test result storage memory 13.

For example, the input circuit 19 outputs a bit mask value BM (˜C2) “1011” obtained by inverting the input expected value comparison result C2 by use of the inverter 23 and supplying the inverted signal via the selector 21 and data DI supplied via the selector 22 to the test result storage memory 13.

Then, the control circuit 15 writes the test result DI into the memory cell MC of the test result storage memory 13 at the same Word address as that of the test memory 12 by use of the bit mask value BM.

For example, the control circuit 15 writes the test result “0100” into the address (Word=2, I/O=0, 1, 2, 3) of the word Word2 of the test result storage memory 13 which is the same as that of the test memory 12 by use of the bit mask value BM (˜C2) “1011”.

By thus writing the test result into the test result storage memory 13 by use of the bit mask value BM, fault information of the same Word address can be written into the test result storage memory without overwriting fault information of another I/O in the step ST2.

<Test Sequence (ST1 to ST3)>

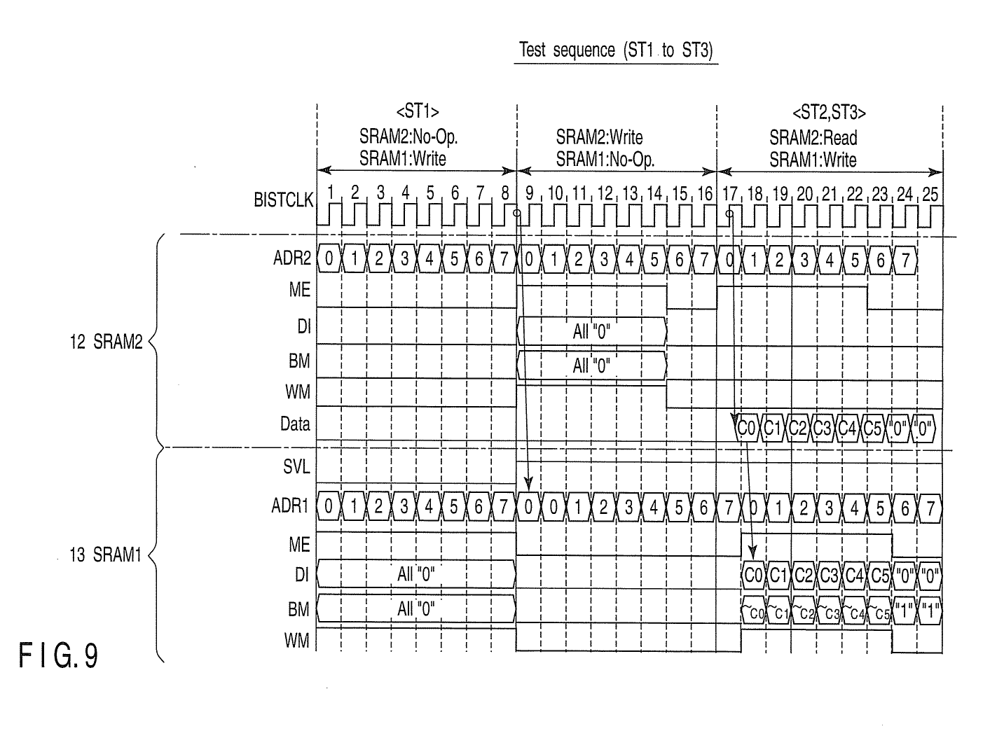

Now, the test sequence of the steps ST1 to ST3 is explained with reference to FIG. 9.

(Step ST1 (Initialization))

As shown in FIG. 9, the control circuit 15 writes initial value “0” data into all of the memory cells MC of the test result storage memory (SRAM1) 13 at the time of clocks BISTCLK1 to BISTCLK8 while a macro enable signal ME is kept at “H” and a write enable signal WM is kept at “H” (initialization).

At the time of clocks BISTCLK1 to BISTCLK8, the control circuit 15 inputs a control signal SVL of “L” to the input circuit 19 to input “0” input data DI (All “0”) to all of the memory cells MC and input “0” bit mask value BM (All “0”) to the test result storage memory 13.

Further, timings of addresses ADR1, ADR2 input to the test memory 12 and test result storage memory 13 at the time of clocks BISTCLK1 to BISTCLK8 are the same.

In this example, the explanation is made by taking an SRAM in which the bit mask value is masked with “1” as an example.

Next, the control circuit 15 outputs a control signal SVL of “H” to the control terminals of the selectors 21, 22, switches the input signal of the input circuit 19 to one of the expected value comparison results C0 to CN and sets an expected value storage mode. Therefore, it sets the test result storage memory 13 into the write mode (SRAM2: Write) and sets the test memory 12 into the non-operative mode (SRAM1: No-Op).

Then, the control circuit 15 inputs “0” input data DI (All “0”) to all of the memory cells MC of the test result storage memory 13 and inputs the “0” bit mask value BM (All “0”) to all of the memory cells MC at the time of clocks BISTCLK9 to BISTCLK16 while the macro enable signal ME in the test memory 12 is kept at “H” and the write enable signal WM is kept at “H” (initialization).

At the time of clock BISTCLK9, the control circuit 15 delays the timing of an address ADR1 input to the test result storage memory 13 by one clock with respect to that of an address ADR2 input to the test memory 12 and outputs the address.

(Steps ST2, ST3)

Next, at the rise time of a clock BISTCLK17, the control circuit 15 performs the test for the test memory 12 at the actual application frequency (at-speed) and outputs an expected value comparison result (after-comparison Data) C0 to the test result storage memory 13 while the macro enable signal ME in the test memory 12 is kept at “H” and the write enable signal WM is kept at “L”.

Then, at the time of a clock BISTCLK18, the control circuit 15 stores data DI (C0) and bit mask signal WM (˜C0) into the test result storage memory 13 while the macro enable signal ME in the test result storage memory 13 is kept at “H” and the write enable signal WM is kept at “H”.

Further, at the time of the clock BISTCLK9, the control circuit 15 delays the timing of an address ADR1 input to the test result storage memory 13 by one clock with respect to that of an address ADR2 input to the test memory 12 and outputs the address. Therefore, at the time of the clock BISTCLK18, the data DI (C0) and bit mask signal WM (˜C0) are stored into the test result storage memory 13 with time delay of one clock. Thus, the control circuit 15 has a function of shifting the addresses ADR1, ADR2 by one clock and outputting the addresses.

As described above, only a faulty portion of the bit mask value BM stored in the test result storage memory 13 is overwritten with input data ˜C0 (“˜” indicates a logical NOT operator) obtained by logically inverting after-comparison Data (C0).

After this, at the time of the clocks BISTCLK19 to BISTCLK22, the control circuit 15 performs the same operation as that performed at the time of the clocks BISTCLK17, BISTCLK18, makes a test for the test memory 12 at the actual application frequency (at-speed) and stores expected value comparison results C1 to C5 into the test result storage memory 13.

In order to enhance the operation speed, it is advantageous to provide F/F circuits between the output of the test result storage memory 13 and the input of the test memory 12 and attain the pipeline operation. In this case, it is desirable to perform the control operation in the control circuit 15 so as to delay the address by the number of clocks delayed by providing the number of F/F circuits.

Further, even when the read/write operations with respect to the test memory 12 are performed out of order, it is possible to cope with this case as in the above case. That is, fault information can be stored into the test result storage memory 13 by setting the test result storage memory 13 into the non-operative state (No Operation State) when the test memory 12 is subjected to the write operation and writing the expected value comparison result into the test result storage memory 13 when the test memory 12 is subjected to the read operation.

(Step ST4 (Repetition of Steps ST1 to ST3—when Different Faulty Cell is Detected at this Time—)

The self test operation of this example is explained with reference to the flow diagram of FIG. 5 again.

The same operation as that of the steps ST1 to ST3 is performed by a preset number of times for all of the memory cells MC in the test memory 12 for each Word.

At this time, when a faulty cell having a different I/O number for the same Word is detected (step ST2), the logical inversion of the expected value comparison result is stored as the bit mask value BM into the test result storage memory 13 (step ST3).

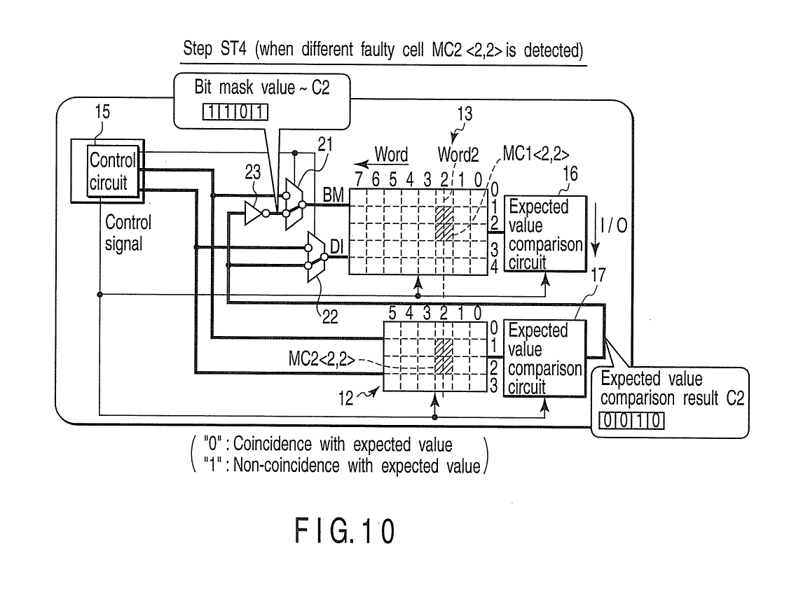

For example, a case wherein a different memory cell MC2<2,2> (Word=2, I/O=2) is detected to be a faulty cell as the expected value comparison result in addition to the memory cell MC2<2,1> (Word=2, I/O=1) for Word2 in the test memory 12 as the result of the re-test as shown in FIG. 10 is explained as an example. In this case, the expected value comparison circuit 17 outputs an expected value comparison result C2 “0010” (Word=2, I/O=0, 1, 2, 3) in Word2 to the input circuit 19.

Next, the input circuit 19 inverts the input expected value comparison result C2 “0010” by use of the inverter 23 and outputs a bit mask value BM (˜C2) “1101” supplied via the selector 21 and data DI supplied via the selector 22 to the test result storage memory 13.

Then, the control circuit 15 performs the write operation for the test result storage memory 13 to store the bit mask value BM (˜C2) “1101” into the address (Word=2, I/O=0, 1, 2, 3) of the same Word2 of the test result storage memory 13 as that of the test memory 12.

According to the steps ST1 to ST4, the faulty memory cell MC can be stored as “1” and the memory cell MC free from the fault can be stored as “0” in the test result storage memory (SRAM1) 13.

(Step ST5 (Test Result Read))

After this, the control circuit 15 slowly reads out data of the test memory (SRAM2) 12 stored in the test result storage memory (SRAM1) 13 at a frequency lower than the actual application frequency.

For example, the frequency used at the test result read time is lower than the actual application frequency (at-speed) and is set to approximately 10 MHz to 50 MHz.

The conventional method can be applied to the above read operation. For example, when a register which temporarily stores read data of the memory cell MC in the expected value comparison circuit 16 is provided, a method for storing the read result for each Word into the register and shifting out the data can be applied.

According to the steps ST1 to ST5, a faulty memory cell corresponding to the address of the test memory (SRAM2) 12 can be specified.

At the time of the step ST5, it is desirable to make the configuration in which the control circuit 15 can perform the read operation.

As described above, according to the BIST circuit device and the self test method thereof of the present embodiment, at least the following effects (1) to (5) are obtained.

(1) A faulty portion can be specified at a product actual application frequency (at-speed).

The BIST circuit device of this example has the test result storage memory 13.

Therefore, fault addresses of all of the memory cells in the test memory 12 including I/O line addresses as well as Word addresses can be acquired. As a result, the faulty portions of the faulty cells can be more precisely specified at the product actual application frequency and the cause of the fault can be easily analyzed.

Particularly, even when the product actual application frequency (at-speed) is a high frequency (a frequency of approximately 100 MHz to 500 MHz which is two to fifty times the frequency at the read time (ST5), for example), it is advantageous in that the faulty portion of the faulty cell can be specified.

(2) The number of additional circuits can be reduced.

The test result storage memory 13 is tested like the other memories in the normal case and accessed from the other logic circuit like the other memories. That is, it is not necessary to provide an exclusive-use memory and another memory provided in the chip can be used. Therefore, the number of additional circuits can be reduced.

(3) Occurrence of a read error can be prevented and the reliability can be enhanced.

Further, the control circuit 15 slowly reads out the test result of the test memory 12 stored in the test result storage memory 13 at a frequency lower than the actual application frequency (step ST5).

Therefore, the test result of the test memory 12 can be read out without fail, occurrence of a read error can be prevented and, as a result, the reliability can be enhanced.

(4) The reproducibility of the test result can be enhanced.

As shown in the test sequence of FIG. 9, the read test of this example can be accessed by use of the same sequence as the test sequence in the normal BIST test.

Therefore, it is advantageous in that a faulty portion which appears only in the specified test sequence can be reproduced and the reproducibility of the test result can be enhanced.

(5) The control operation of the self test operation can be simplified.

In this example, at the time of the step ST3, the control circuit 15 stores the test result into the test result storage memory 13 and the process can be performed within the BIST circuit device 11 (for example, in the chip).

Therefore, for example, even when a PLL circuit (Phase Locked Loop circuit: a circuit which outputs a signal at a frequency equal to an integral multiple of the frequency of an input signal and is used when a high-frequency clock is generated in the chip) is used, the self test can be made within the BIST circuit device 11 and the control operation of the self test operation can be simplified if the clock is supplied from the exterior.

### Second Embodiment

### One Example Having a Plurality of Test Memories

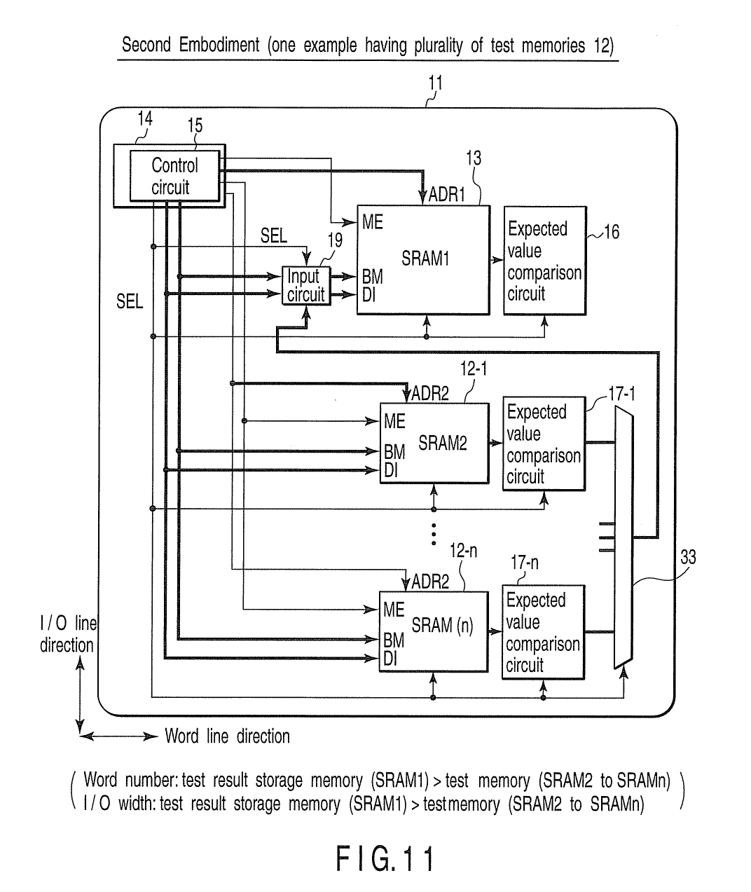

Next, a BIST circuit device according to a second embodiment of this invention is explained with reference to FIG. 11. The present embodiment relates to one example in which a plurality of test memories are provided and it is expanded to store the results of the test memories. In this explanation, the detail explanation for portions which are the same as those of the first embodiment is omitted.

As shown in FIG. 11, the BIST circuit device 11 of this example is different from that of the first embodiment in the following points.

First, the present embodiment is different from the first embodiment in that a plurality of (n) test memories 12-1 to 12-n (SRAM2 to SRAM(n)), a plurality of expected value comparison circuits 17-1 to 17-n which compare the test results of the test memories 12-1 to 12-n with expected values and a multiplexer 33 are provided.

The multiplexer 33 is configured to select outputs of the expected value comparison results of the test memories 12-1 to 12-n (SRAM2 to SRAM(n)) according to a control signal SEL and output the selected comparison result to an input circuit 19.

Further, the Word number and I/O width of a test result storage memory 13 (SRAM1) in the present embodiment are set larger than the Word number and I/O width of the test memories 12-1 to 12-n (SRAM2 to SRAM(n)) (Word number: SRAM1>SRAM2 to SRAM(n), I/O width: SRAM1>SRAM2 to SRAM(n)).

Likewise, in the self test operation, the process of the steps ST1 to ST5 is performed for all of the memory cells in the test memories 12-1 to 12-n. Then, all of the test results of the test memories 12-1 to 12-n are stored into the test result storage memory 13.

The other configuration and operation are substantially the same as those of the first embodiment, and therefore, the detail explanation thereof is omitted.

As described above, according to the BIST circuit device of the present embodiment, the same effects as the effects (1) to (5) can be attained.

Further, according to the present example, the configuration is made to include a plurality of test memories 12-1 to 12-n and set the Word number and I/O width of the test result storage memory (SRAM1) larger than the Word numbers and I/O widths of the test memories 12-1 to 12-n (SRAM2 to SRAM(n)) (Word number: SRAM1>SRAM2 to SRAM(n), I/O width: SRAM1>SRAM2 to SRAM(n)).

Therefore, this invention can be applied to the configuration having the test memories 12-1 to 12-n as in this example as required.

### Third Embodiment

### One Example Having a Plurality of Test Result Storage Memories

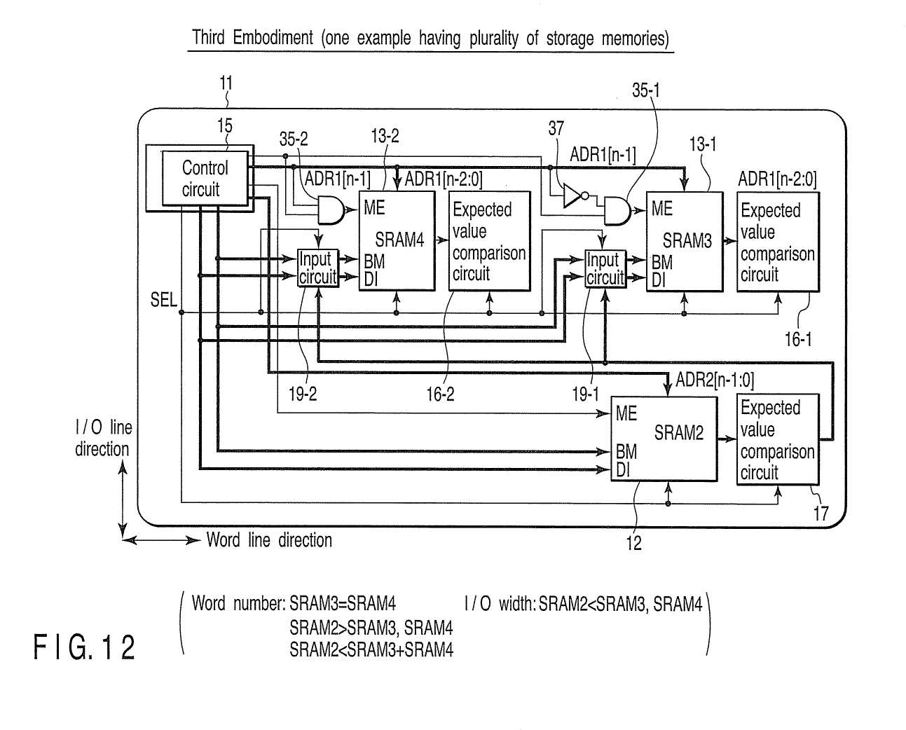

Next, a BIST circuit device according to a third embodiment of this invention is explained with reference to FIG. 12. The present embodiment relates to an example in which a plurality of (two in this example) test result storage memories are provided and test results are separately stored into the test result storage memories. In this explanation, the detail explanation for portions which are the same as those of the first embodiment is omitted.

<Configuration>

As shown in FIG. 12, the BIST circuit device 11 of the present embodiment is different from that of the first embodiment in that test result storage memories 13-1, 13-2 (SRAM3, SRAM4), expected value comparison circuits 16-1, 16-2 set to correspond to the memories 13-1, 13-2, input circuits 19-1, 19-2, NOT circuit 37 and AND circuits 35-1, 35-2 are provided.

In this case, the Word number in the test result storage memories 13-1, 13-2 is the same (Word number: SRAM3=SRAM4).

The Word number of the test memory 12 is set larger than the Word number in the test result storage memories 13-1, 13-2 (Word number: SRAM2>SRAM3, SRAM4), but the Word number of the test memory 12 is set smaller than the sum of the Word numbers of the test result storage memories 13-1, 13-2 (Word number: SRAM2<SRAM3+SRAM4).

Further, the I/O width of the test memory 12 is set smaller than the I/O width of the test result storage memories 13-1, 13-2 (I/O width: SRAM2<SRAM3, SRAM4).

The input circuits 19-1, 19-2 are configured to selectively output an output of the expected value comparison circuit 17 to one of the test result storage memories 13-1, 13-2 as a bit mask value or data DI according to the control signal SEL from the control circuit 15.

The NOT circuit 37 is configured to logically invert the output signal of the expected value comparison circuit 17 which is the input most significant bit and output the inverted signal to the AND circuit 35-1.

The AND circuit 35-1 is configured to receive a macro enable signal output from the control circuit 15 and an output signal of the NOT circuit 37, calculate the logical AND of the received signals and output the logical AND signal to the test result storage memory (SRAM3) 13-1 as a macro enable signal ME.

The AND circuit 35-2 is configured to receive a macro enable signal output from the control circuit 15 and an output signal of the expected value comparison circuit 17 which is the most significant bit, calculate the logical AND of the received signals and output the logical AND signal to the test result storage memory (SRAM4) 13-2 as a macro enable signal ME.

<Self Test Operation>

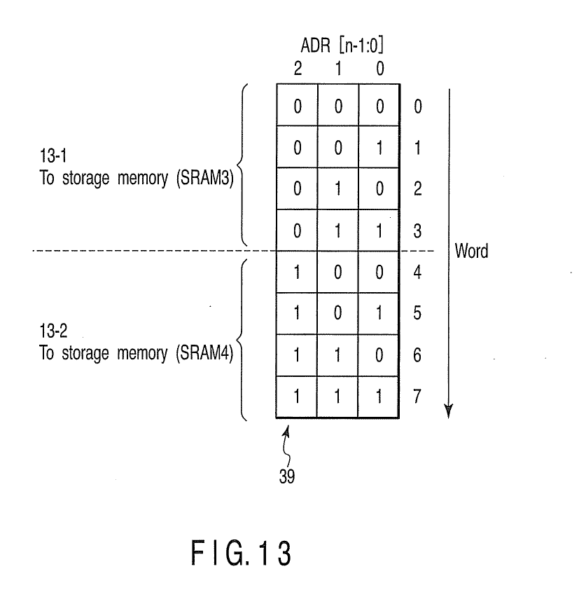

Next, the self test operation of this example is explained with reference to FIG. 13. FIG. 13 is a diagram for illustrating the self test operation of this example.

First, the operation which is the same as that of the steps ST1, ST2 is performed.

Then, as shown in FIG. 13, at the time of the step ST3 (at the time of storage of the test result), the process of determining one of the test result storage memories (SRAM3, SRAM4) 13-1, 13-2 into which the test result is to be stored by use of the most significant bit 39 of the test memory (SRAM2) 12 is performed.

Specifically, the logical AND of the macro enable signal ME output from the control circuit 15 and a NOT signal of the most significant bit is input as the macro enable signal ME of the test result storage memory (SRAM3) 13-1 and the logical AND of the macro enable signal ME output from the control circuit 15 and the most significant bit is input as the macro enable signal ME of the test result storage memory (SRAM4) 13-2.

Therefore, the control circuit 15 only generates the same control signal as that obtained when both of the Word number and the I/O width are large and the expected value comparison result is stored into the test result storage memory (SRAM3) 13-1 in a period in which the most significant bit 39 of the address is kept at “0”. On the other hand, the expected value comparison result is stored into the test result storage memory (SRAM4) 13-2 in a period in which the most significant bit 39 of the address is kept at “1”.

After this, the same operation as that of the steps ST4, ST5 of the first embodiment is performed and the self test operation of this example is terminated.

In this example, a case wherein the two test result storage memories 13-1, 13-2 are provided and the memories separately store data items of the same Word number is explained as an example. However, this invention is not limited to the above case and, for example, even if three or more test result storage memories are provided and the memories have different Word numbers, this invention can be similarly applied by using the upper bits of the Word address and additionally performing the other adequate logical operations.

As described above, according to the BIST circuit device of the present embodiment, the same effects as the effects (1) to (5) can be attained.

Further, the same configuration as that of this example can be applied as required.

### Fourth Embodiment

### One Example Having a Plurality Of Test Result Storage Memories)

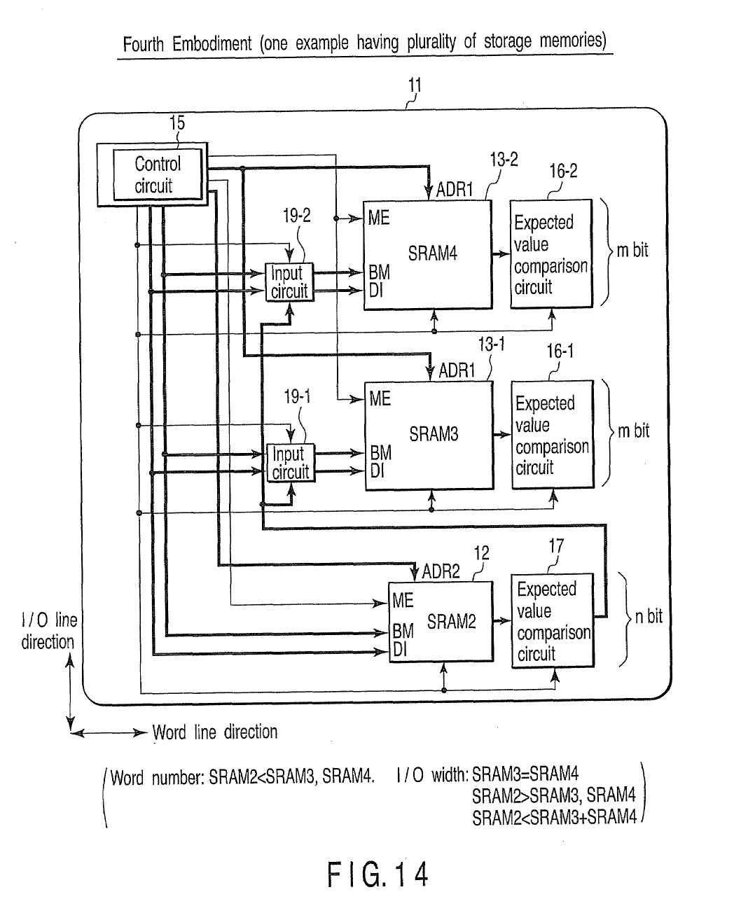

Next, a BIST circuit device according to a fourth embodiment of this invention is explained with reference to FIG. 14. The present embodiment relates to an example in which two test result storage memories 13-1, 13-2 are provided and expanded to store expected value comparison results of larger I/O widths. In this explanation, the detail explanation for portions which are the same as those of the first embodiment is omitted.

### Configuration Example

As shown in FIG. 14, the BIST circuit device 11 according to the present embodiment is different from that of the first embodiment in that it includes the test result storage memories (SRAM3, SRAM4) 13-1, 13-2, expected value comparison circuits 16-1, 16-2 and input circuits 19-1, 19-2 which are respectively provided in correspondence to the memories 13-1, 13-2.

In this case, the Word number of the test memory 12 of this example is set smaller than that of the test result storage memories 13-1, 13-2 (Word number: SRAM2<SRAM3, SRAM4). However, the Word number is only required to satisfy the above condition and can be set to a different value.

Further, the I/O widths of the test result storage memories 13-1, 13-2 are set to the same value (I/O width: SRAM3=SRAM4). The I/O width of the test memory 12 is set larger than the I/O width of each of the test result storage memories 13-1, 13-2 (I/O width: SRAM2>SRAM3, SRAM4) and set smaller than the sum of the I/O widths of the test result storage memories 13-1, 13-2 (I/O width: SRAM2<SRAM3+SRAM4)

<Self Test Operation>

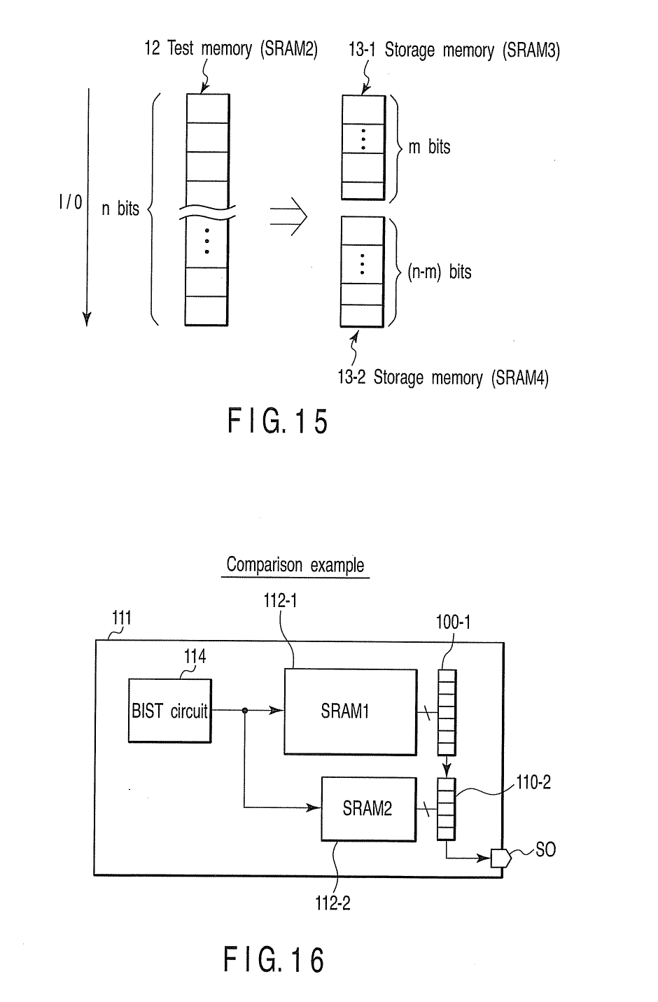

Next, the self test operation of this example is explained with reference to FIG. 15. FIG. 15 is a diagram for illustrating the self test operation of this example.

First, the operation which is the same as that of the steps ST1, ST2 is performed.

Then, as shown in FIG. 15, at the time of the step ST3 (at the time of storage of the test result), the expected value comparison result of the test memory (SRAM2) 12 is divided into upper-bit and lower-bit portions which are respectively stored into the test result storage memories (SRAM3, SRAM4) 13-1, 13-2.

Specifically, the explanation is made by taking a case wherein the I/O width of the test memory 12 is n bits and the I/O width of the test result storage memories 13-1, 13-2 is m bits as an example.

In this case, the connection is made to input C[m−1: 0] which is the lower m bits in the expected value comparison result C[n−1: 0] to the input circuit 19-1 corresponding to the memory 13-1 and input C[n-m−1: m] which is the upper (n-m) bits to the input circuit 19-2 corresponding to the memory 13-2.

Therefore, the control circuit 15 only generates a control signal which is the same as that obtained when both of the Word number and I/O width are larger and can store the lower m bits of the expected value comparison result into the memory 13-1 and store the upper (n-m) bits into the memory 13-2.

After this, the same operation as that of the steps ST4, ST5 of the first embodiment is performed and the self test operation of this example is terminated.

In this example, the separate storage operation is explained by taking a case wherein the two test result storage memories 13-1, 13-2 are provided and the I/O widths of the memories are the same as an example. However, this invention is not limited to the above case and, for example, even if the separate storage operation is performed when three or more test result storage memories are provided and different I/O widths are set, the same operation can be attained by changing a connection destination of the expected value comparison result circuit 17.

As described above, according to the BIST circuit device of the present embodiment, at least the same effects as the effects (1) to (5) can be attained.

Further, the same configuration as that of this example can be applied as required.

Although the detail explanation is omitted, for example, a combination of a case where the Word number and I/O width are both smaller than those of the test memory 12 or other various combinations can be applied by combining the second to fourth embodiments.

### Comparison Example

Next, a BIST circuit device of a comparison example is explained with reference to FIG. 16 in order to compare the above BIST circuit device and self test method thereof with the BIST circuit device and self test method thereof according to the first to fourth embodiments.

As shown in FIG. 16, the present embodiment is different from the first to fourth embodiments in that the BIST circuit device (chip) 111 of the comparison example includes test memories 112-1, 112-2 and registers 100-1, 110-2 but does not include the control circuit 15 and test result storage memory 13 (the test memory cannot be used as the test result storage memory).

Further, the present embodiment is different from the first to fourth embodiments in that the self test operation cannot be performed at a product actual application frequency (at-speed) in the self test operation of the BIST circuit device 111 of the comparison example since the control circuit 15 is not provided.

When a PLL circuit (Phase Locked Loop circuit: a circuit which outputs a signal at a frequency equal to an integral multiple of the frequency of an input signal and is used when a high-frequency clock is generated in the chip) is used, the faulty portion of a faulty memory cell (fail bit) can only specify a Word address (Word number) and cannot specify an I/O address (I/O width). This is because the BIST circuit device 111 of the comparison example does not include the test result storage memory 13 and the test result cannot be stored. As a result, the reliability is lowered.

In order to specify the I/O address (I/O width), it is considered that read results for each Word can be serially output from the shift-out terminal SO. However, when the PLL circuit is used, it is difficult to control the shift-out timing from the exterior. Further, while the shift-out operation is being performed, the reproducibility is lowered depending on the operation sequence in some cases (the fault does not reappear) since the test memories 112-1, 112-2 repeatedly perform the operation which has been performed immediately before the present cycle.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A BIST circuit device comprising:
a test memory;
a test result storage memory having capacity not smaller than capacity of the test memory; and
a control circuit which performs a test for the test memory at an actual application frequency and stores a test result into the test result storage memory.

2. The device according to claim 1, further comprising an input circuit which selectively fetches a signal according to a control signal input from the control circuit and outputs the selected signal to the test result storage memory.

3. The device according to claim 2, further comprising a first expected value comparison circuit which compares data read out from the test memory with an expected value and outputs a comparison result to the input circuit.

4. The device according to claim 2, further comprising a second expected value comparison circuit which compares data read out from the test result storage memory with an expected value, outputs a comparison result and reads out data from the test result storage memory.

5. The device according to claim 1, wherein the test memory includes a plurality of test memories.

6. The device according to claim 5, further comprising an input circuit which selectively fetches a signal according to a control signal input from the control circuit and outputs the selected signal to the test result storage memory; and a plurality of first expected value comparison circuits which compare data items read out from the plurality of test memories with expected values and output comparison results to the input circuit.

7. The device according to claim 1, wherein the test result storage memory includes a plurality of test result storage memories.

8. The device according to claim 7, further comprising a plurality of second expected value comparison circuits which compare data items read out from the plurality of test result storage memories with expected values, output comparison results and read out data items from the plurality of test result storage memories.

9. The device according to claim 2, wherein the input circuit includes a first selector which selects one of a test signal input from the control circuit at a normal test time and a signal of logical NOT of an expected value comparison result input from the first expected value comparison circuit according to the control signal and outputs the thus selected signal to the test result storage memory; a second selector which selects one of a normal test input signal input from the control circuit and a signal of the expected value comparison result input from the first expected value comparison circuit according to the control signal and outputs the thus selected signal to the test result storage memory; and an inverter which inverts the expected value comparison result input from the first expected value comparison circuit and outputs the thus inverted signal to the first selector.

10. The device according to claim 1, wherein the test memory and the test result storage memory have memory cells arranged in intersecting positions between a plurality of word lines and a plurality of bit lines in a matrix form and the memory cells are accessed by using a common one of the word lines with a plurality of Words used as one unit for each I/O width with a plurality of bit lines selected by a column selection circuit used as one unit.

11. A BIST circuit device comprising:
a plurality of test memories;
a test result storage memory having capacity not smaller than capacity of the test memories; and
a control circuit which performs tests for the plurality of test memories at an actual application frequency and stores test results into the test result storage memories.

12. The device according to claim 11, further comprising a plurality of expected value comparison circuits which are provided in correspondence to the plurality of test memories and compare data items read out from the plurality of test memories with expected values.

13. The device according to claim 12, further comprising a multiplexer configured to selectively fetches outputs of a plurality of expected value comparison results according to a control signal from the control circuit.

14. The device according to claim 11, wherein the test memories and the test result storage memory have memory cells arranged in intersecting positions between a plurality of word lines and a plurality of bit lines in a matrix form and the memory cells are accessed by using a common one of the word lines with a plurality of Words used as one unit for each I/O width with a plurality of bit lines selected by a column selection circuit used as one unit, and the test result storage memory includes a plurality of test result storage memories in which at least the I/O width for each Word is larger than the I/O width for each Word of the test memory and a sum of Word numbers is larger than a Word number of each of the test memories.

15. The device according to claim 14, wherein the control circuit selectively determines one of the plurality of test result storage memories into which the test result is stored by use of an upper bit of a Word address at the test time when the test results are stored into the plurality of test result storage memories.

16. A self test method for a BIST circuit device including a test memory, a test result storage memory having capacity not smaller than capacity of the test memory and a control circuit comprising:
causing the control circuit to perform a test for the test memory at an actual application frequency and causing a test result to be stored into the test result storage memory.

17. The self test method according to claim 16, further comprising causing the control circuit to initialize all memory cells in the test result storage memory before the control circuit performs the test for the test memory at the actual application frequency and stores the test result into the test result storage memory.

18. The self test method according to claim 16, further comprising repeatedly performing an operation of causing the control circuit to perform the test for the test memory at the actual application frequency and causing the test result to be stored into the test result storage memory by a preset number of times.

19. The self test method according to claim 18, wherein the control circuit reads out data of the test memory stored in the test result storage memory at a frequency lower than the actual application frequency.

20. The self test method according to claim 16, wherein the BIST circuit device further includes an input circuit which selectively fetches a signal according to a control signal input from the control circuit and outputs the selected signal to the test result storage memory; a first expected value comparison circuit which compares data read out from the test memory with an expected value and outputs a comparison result to the input circuit; and a second expected value comparison circuit which compares data read out from the test result storage memory with an expected value, outputs a comparison result and reads out data from the test result storage memory.
